(19) United States
(12) Patent Application Publication
(10) Pub. No.: US 2013/0153995 A1
(43) Pub. Date: Jun. 20, 2013

(54) SEMICONDUCTOR DEVICE AND METHOD FOR MANUFACTURING THE SAME

(71) Applicants: Hiroto MISAWA, Ishikawa-ken (JP); Hideki Okumura, Kanagawa-ken (JP)

(72) Inventors: Hiroto MISAWA, Ishikawa-ken (JP); Hideki Okumura, Kanagawa-ken (JP)

(73) Assignee: KABUSHIKI KAISHA TOSHIBA, Tokyo (JP)

(21) Appl. No.: 13/607,449

(22) Filed: Sep. 7, 2012

(30) Foreign Application Priority Data
Dec. 14, 2011 (JP) 2011-273275

(51) Int. Cl. H01L 29/78; H01L 21/336

(52) U.S. Cl. 257/330; 438/270; 257/E29.262; 257/E21.41

(57) ABSTRACT

A semiconductor device includes a first region with second conductivity type formed over a semiconductor layer with first conductivity type. On this first region, the second region of the first conductivity type is selectively provided. On the same first region, a third region of second conductivity type is also selectively provided and is adjoined to the second region. The first control electrode is provided within a trench located deeper than the first side of the second region compared to the first region. The first control electrode includes a part opposed to the first and second regions separated by a first insulator, and a second part opposed to the semiconductor layer separated by a thicker second insulator. Inside the trench, the second control electrode is provided between the trench bottom and the first control electrode. The second control electrode is opposed to the semiconductor layer through a third insulator.

### CROSS-REFERENCE TO RELATED APPLICATION

This application is based upon and claims the benefit of priority from Japanese Patent Application No. 2011-273275, filed Dec. 14, 2011; the entire contents of which are incorporated herein by reference.

### FIELD

Embodiments described herein relate to a semiconductor device and a method for manufacturing the same.

### BACKGROUND

Semiconductor devices as represented by a metal-oxide-semiconductor field-effect transistor (MOSFET), are widely used in applications such as power control. In order to reduce power loss, both the on-resistance, and the input capacitance, need to be small. However, the values of on-resistance and input capacitance commonly are dictated by design and material considerations which make it difficult to reduce both of them at the same device. As a result, a semiconductor device that having a trench gate structure with field plates has been pursued.

An example of related art includes Patent Reference of JP-A-2011-159763.

### DESCRIPTION OF THE DRAWINGS

FIG. 1 is a schematic profile showing the semiconductor device of the first embodiment to be described herein.

FIGS. 2A and 2B are schematic profiles representing the results of steps of the manufacturing process in a semiconductor substrate to yield the semiconductor device of the first embodiment.

FIGS. 3A to 3C are further schematic profiles representing the profiles representing the results of steps of the manufacturing process in a semiconductor substrate to yield the semiconductor device of the first embodiment.

FIGS. 4A to 4C are further schematic profiles representing the manufacturing process profiles representing the results of steps of the manufacturing process in a semiconductor substrate to yield the semiconductor device of the first embodiment.

FIGS. 5A to 5C are further schematic profiles representing the manufacturing process profiles representing the results of steps of the manufacturing process in a semiconductor substrate to yield the semiconductor device of the first embodiment.

FIGS. 6A to 6C are schematic profiles representing the manufacturing process of the semiconductor device in a second embodiment.

FIGS. 7A to 7C are further schematic profiles representing the manufacturing process profiles representing the results of steps of the manufacturing process in a semiconductor substrate to yield the semiconductor device of the second embodiment.

FIG. 8 is a schematic profile showing a semiconductor device in the second embodiment.

FIGS. 9A and 9B are graphs showing the characteristics of a semiconductor device.

### DETAILED DESCRIPTION

In general, according to one embodiment, the following paragraphs explain the embodiment, in part with reference to the drawings. Elements of the embodiments are explained in referring to the related reference numbers that appear in the drawings in order to provide a detailed and concise explanation. In addition, Cartesian coordinates, XYZ, are used in the figures, but solely for purposes of explanation and not to limit the embodiments to particular two- or three-dimensional embodiments. In the following embodiment explanation, n-type refers to the first conductivity type, and p-type refers to the second conductivity type. Please note that this does not limit the embodiments to a particular dopant paradigm, as it is also acceptable to reverse the dopant paradigm, using a p-type dopant for the first conductivity type and an n-type dopant for the second. Also, silicon wafer is used as an example of a semiconductor layer, but other compound semiconductors such as gallium nitride (GaN) and silicon carbide (SiC) are also applicable. As for the insulator film, silicon oxide is specified as an example; of course, it is also possible to use other insulators, such as silicon nitride or silicon oxy-nitride.

According to one embodiment, there is provided a semiconductor device having both reduced on-resistance and input capacitance, and a method of manufacturing the device is also provided.

The semiconductor device in this embodiment provides the semiconductor layer of the first conductivity type; on this layer is the first region of the second conductivity type; on this first region is the second region of the first conductivity type, which had been selectively prepared; then, still on this first region, the third region of the second conductivity type, which had also been selectively prepared, is joined to the second region. Then, from the first side of the second region, the first control electrode will be formed inside a trench that reaches an even deeper position than the first region mentioned above. The first part, which is opposed to the first and the second regions, will be separated by the first insulator, while the second part, which is opposed to the semiconductor layer, is separated by the second insulator, which is even thicker than the first one. Between the first control electrode and the interior bottom of the trench, the second control electrode is formed, opposed to the semiconductor layer separated by the third insulator, which is even thicker than the second. In addition, this first main electrode, which is electrically connected to the semiconductor layer, then to the second and the third regions, is electrically connected to the second main electrode.

### EMBODIMENT 1

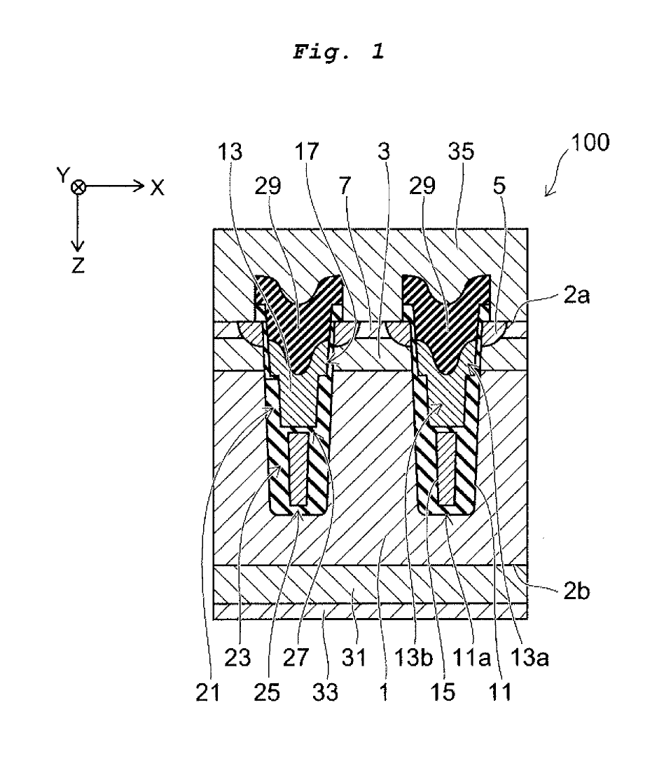

FIG. 1 is a schematic profile showing the first embodiment of the semiconductor device 100. This semiconductor device 100 is the MOSFET used, for example, for power control in the trench gate structure.

FIG. 1 shows a cross-section of the unit cell in the plane XZ of the semiconductor device 100. The semiconductor device 100 provides an n-type drift layer 1, which represents the semiconductor layer of the first conductivity type, a p-type base region 3, which is the first region of the second conductivity type, an n-type source region 5, which represents the second region of the first conductivity type, and a p-type contact region 7, which is the third region of the second conductivity type.

P-type base region 3 is provided on the n-type drift layer 1, while n-type source region 5 is selectively provided on top of the p-type base region 3, some of which extends into the upper surface of the p-type base region 3. P-type contact region 7 is adjoined to the n-type source region 5 and is also selectively prepared on top of the p-type base region 3. P-type contact region 7 can also be formed in the bottom of the trench, from the surface 2a (the first side) on top of the n-type source region 5 in the direction of the rear surface 2b (the second side) of the n-type drift layer 1 (direction Z).

In addition gate electrode 13, which is the first control electrode, is formed inside trench 11, which extends from the surface 2a of the n-type source region 5 to terminate within the n-type drift layer 1 at trench bottom 11a. Trench 11 also extends in the Y direction (into or out of the plane of FIG. 1, at a distance greater than the extent or span of p-type base region 3 in direction Z. In addition, field plate electrode 15, which is the second control electrode, is formed between the bottom 11a of the trench 11 and gate electrode 13.

Gate electrode 13 includes a first part 13a, which is opposed to n-type source region 5 and p-type base region 3 and separated therefrom by gate insulator 17 (the first insulator), and a second part 13b, which is opposed to n-type drift layer 1 and separated therefrom by field plate insulator 21 (the second insulator), which is thicker from the edge of gate electrode 13 to the n-type drift layer than is gate insulator 17 extending between gate electrode and adjacent portions of the n-type source region 5 and p-type base region 3.

Field plate electrode 15 is opposed to n-type drift layer 1, and separated therefrom by field plate insulator 23 (the third insulator), which is thicker than field plate insulator 21 in the lateral direction from the side of the field plate electrode 15 to the adjoining drift layer 1. In the bottom of trench 11, field plate electrode 15 is opposed to n-type drift layer 1 separated by field plate insulator 25 (the fourth insulator), which is thinner in span to the adjacent drift layer than field plate insulator 23.

Field plate electrode 15 is opposed to, and disposed inwardly of the trench than, gate electrode 13 and separated therefrom by insulator 27, which is the fifth insulator. In addition, the area of the part where field plate electrode 15 is opposed to gate electrode 13 is smaller than the thickness of the other areas where gate electrode 13 faces field plate electrode 15.

Gate insulator 17, field plate insulators 21, 23, and 25, and insulator 27 are preferably configured as a continuous layer of silicon oxide material with intervening materials within the trench 11.

The semiconductor device 100 also includes a n-type drain layer 31 connected to the rear surface 2b of the n-type drift layer 1, to form a drain electrode 33 (the first main electrode), which is electrically connected to n-type drift layer 1.

Furthermore, the semiconductor device 100 provides source electrode 35 (the second main electrode) on the surface 2a of n-type source region 5 and p-type contact region 7; n-type source region 5 and p-type contact region 7 are electrically connected to source electrode 35.

P-type contact region 7 electrically connects p-type base region 3 and source electrode 35; so the holes that have been accumulated in p-type base region 3 are discharged into source electrode 35. In addition, field plate electrode 15 is held to the same potential because it is electrically connected (connection not shown) to source electrode 35.

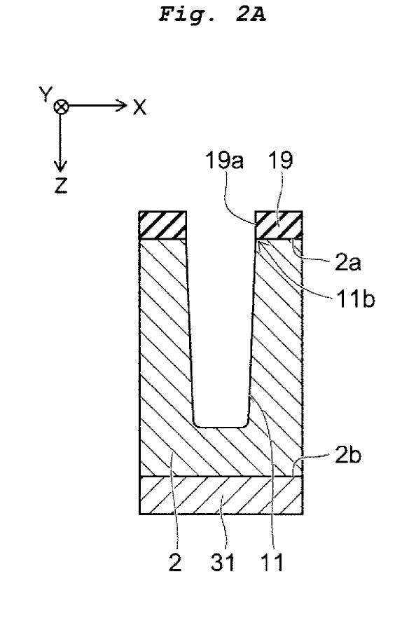

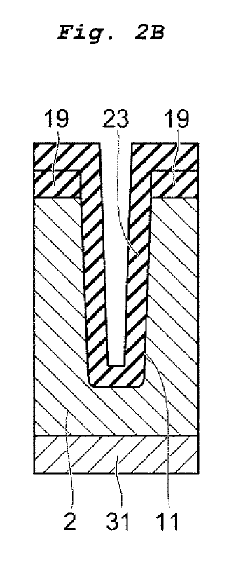

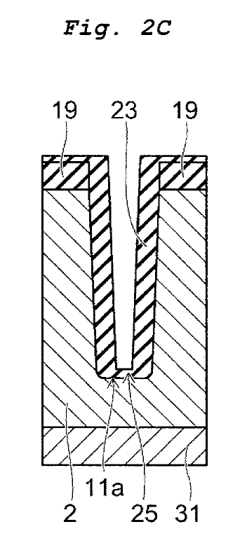

Next, the method of manufacturing a semiconductor device according to the present embodiment is explained by referring to FIGS. 2A to 5C. FIGS. 2A to 5C are schematic sectional profiles showing the manufacturing process of the semiconductor device 100.

As shown in FIG. 2A, a trench 11 is formed in n-type layer 2. On the surface 2a of n-type layer 2, a silicon oxide 19 layer is first formed continuously over a continuous n=type layer, i.e., before the trench 11 is formed. used The silicon oxide layer will be used as a mask, in order to etch the trench 11 into the n-type layer 2. For this etching, the silicon oxide layer 19 is covered with an additional patternable material, such as a photoresist (not shown), which is itself patterned using photolithographic techniques which are known in the art, to yield apertures therethrough. Then, for example, an RIE (reactive-ion etching) technique is used to anisotropically etch the underlying silicon oxide, and then the underlying doped n-type layer, to form the trench 11. The resist (not shown) can be removed following opening the apertures 19a in the silicon oxide hard mask 19, or, may remain in place while the trench is etched into n-doped layer 2. In this case, the speed of the etching in direction Z is faster than the speed in direction X.

N-type layer 2 is, for example, an epitaxial layer formed on the surface of a silicon wafer (not shown in the figure). Then, n-type drain layer 31 can be formed between n-type layer 2 and silicon wafer, or the silicon wafer itself can turn out to be n-type drain layer 31. The carrier density of n-type layer 2 can be, for example, 1-4×10¹⁶ atoms/cm³, while its thickness can be 4-11 micrometers (μm). Also, the carrier density of n-type drain layer 31 can be, for example, 2-8×10¹⁹ atoms/cm³.

The aperture 19a is formed in a stripe-shaped pattern that extends indirection Y, and thus is deeper in the direction in and out of the Fig. (Y direction) than to the right and left (X-direction)in the Fig. to form an elongated trench. The opening side lib of trench 11, for example, equals the size of the opening side 19a of the etching mask; the width in direction X is 1-2 μm. The depth of trench 11 in direction Z equals the depth across p-type base region 3, for example, 4-6 μm.

Next, as shown in FIG. 2B, field plate insulator 23 is formed inside trench 11, aperture 19a and over the field region (upper or outer surface of) silicon oxide layer 19. Field plate insulator 23 is in this embodiment a silicon oxide layer formed by using the CVD (chemical vapor deposition) technique or by thermal oxidation (wherein an oxide layer would be grown in situ on the walls of the silicon material bounding the trench). The thickness of the field plate insulator 23 formed on the side wall of trench 11 in direction X can be around 0.3-0.6 μm.

The formation of lowermost field plate insulator 25, i.e., that which extends between the base of the field plate electrode 15 and the underlying drift layer 2 as shown in FIG. 1) to the desired thickness is provided by etching field plate insulator 23 layer, which had been formed in the bottom 11a of trench 11. The thickness of field plate insulator 25 in direction Z is, for example, 0.2-0.3 μm. In addition, using anisotropic etching, which preferably etches in direction Z, instead of etching the part that had been formed on the side wall of field plate insulator 23, it is possible to etch the part formed on the bottom 11a and the field of the silicon oxide layer 19 without significant etching of the layer on the sidewalls of the trench.

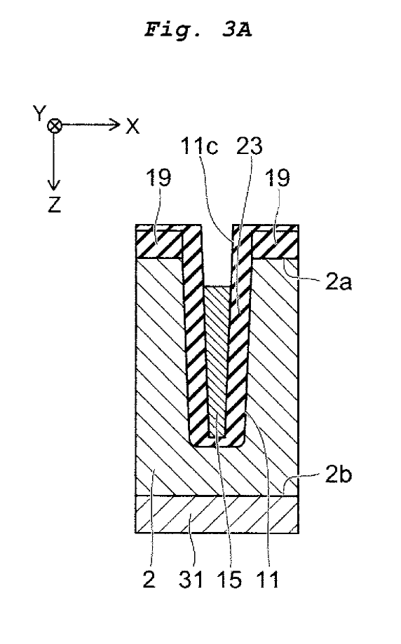

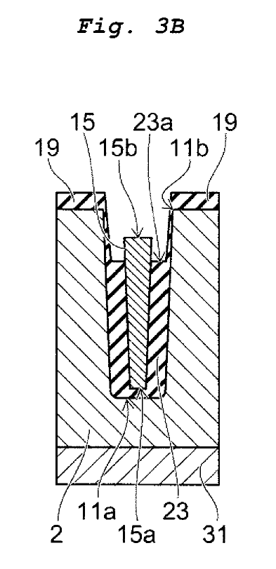

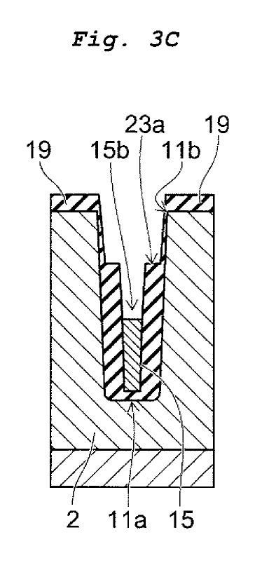

Now, as shown in FIGS. 3A to 3C, field plate electrode 15 is formed to be embedded in the void 11c inside trench 11 where field plate insulator film 23 is formed. Field plate electrode 15 can be, for example, polycrystalline silicon of the conductivity doped by n-type impurities.

For example, a CVD technique is used to generate a polycrystalline silicon stud or plug over the field insulating layer 23 within the trench as shown in FIG. 3A, and then etch back the adjacent field plate insulator 23 to yield a stud of plug at the lower portion of the trench. As a result, it is possible to form a field plate electrode 15 inside trench 11.

Next, as shown in FIG. 3B, the field plate insulator film 23 is etched back in direction Z to reach a depth intermediate of the span of the top 15b of the stud for forming the field plate electrode 15 to the bottom 11a in the trench 11.

For example, a selective wet-etching technique, which etches the field plate insulator film 23 without significantly effecting the silicon oxide layer 19 such that silicon oxide 19 remains on the surface of n-type layer 2, is used. Etching is terminating while a thin layer of field plate insulator film 23 on the upper side wall of trench 11 remains after etching.

Next, as shown in FIG. 3C, the field plate electrode 15 is etched back to reach the depth intermediate of the edge of the opening side 23a of trench 11 of field plate insulator 23 and the bottom 11a of trench 11. For this etching, for example, the CDE (chemical dry etching) technique is used. In this case, the silicon oxide 19 remaining on the surface 2a of n-type layer 2 and the field plate insulator 23 remaining on the side wall of trench 11 will protect the surface of n-type layer 2 from the etchant.

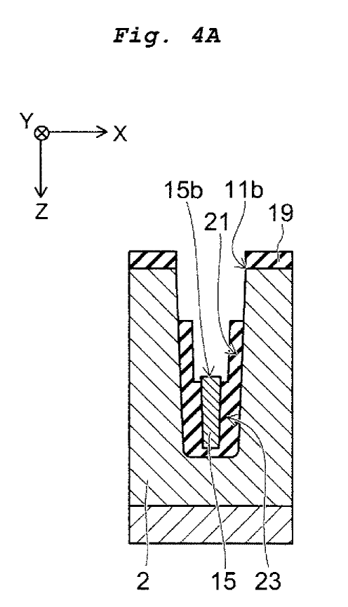

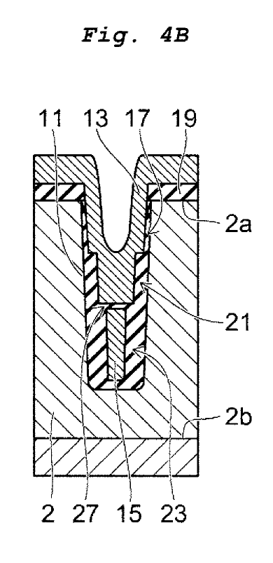

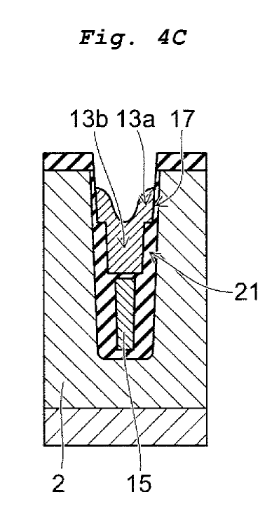

Now, as shown in FIG. 4A, the field plate insulator 23 located between the opening side lib of trench 11 and the edge of the opening side 15b of trench 11 of field plate electrode 15 is etched in order to make the inner surface of trench 11 thinner in the x-direction in the Fig. (and in the y direction at the ends of the trench, not shown). The wet-etching technique, for example, is used to make the prescribed thickness of field plate insulator 23 thinner in order to form field plate insulator 21. Also, the thin remaining insulating film (FIG. 30) which extended from the upper terminus of the field plate insulator 21 and the opening side 11b is removed in order to expose the side walls of trench 11 in that area.

Next, as shown in FIG. 4B, thermal oxidation is used on the exposed side walls of trench 11 to form gate insulator 17. After gate insulator 17 is formed, a gate electrode 13 film is formed conformally on the exposed portions of the trench 11. It is possible to use a CVD technique to form the gate electrode 13 material, for example, when polycrystalline silicon is doped by n-type impurities. Gate insulator 17 can also be formed, for example, by thermal oxidation using dry oxygen (dry O₂).

Then, as shown in FIG. 4C, the gate electrode 13 material is etched back to remove the portions thereof overlying the surface 2a of n-type layer 2 and exposing a portion of the gate insulator 17. As A result of this process, the first part 13a and the second part 13b of gate electrode 13 are formed inside trench 11.

Conditions of anisotropic etching of RIE are used, for example, in order to etch the gate electrode 13 material to form the gate electrode as shown in FIG. 4C. More precisely, because the etching speed in direction Z is faster than that of direction X, the volume of etching in direction Z will be greatly in excess of that indirection.

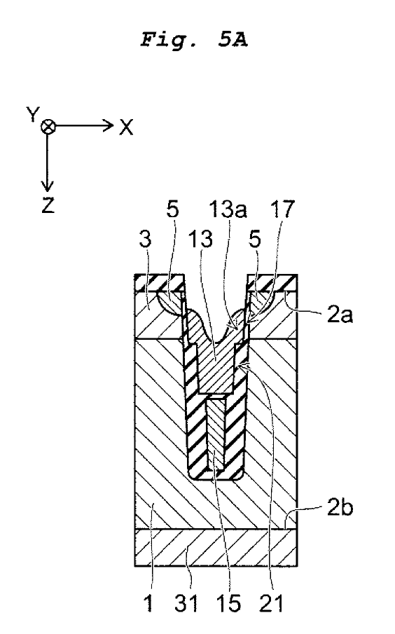

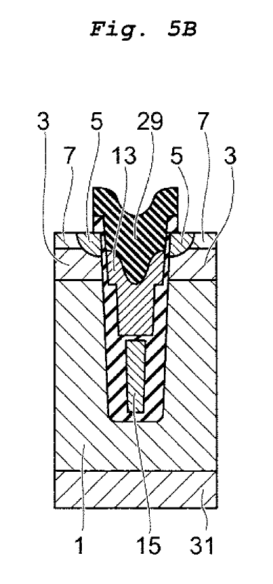

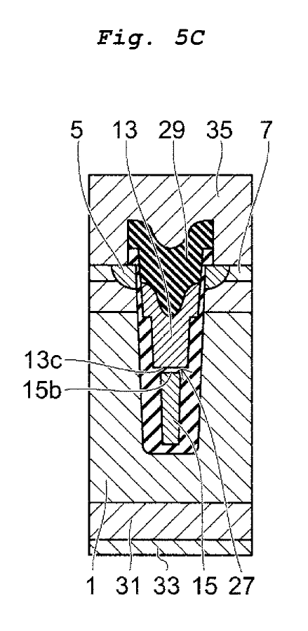

Next, as shown in FIG. 5A is the formation of p-type base region 3 and n-type source region 5 on the surface 2a of n-type layer 2. P-type base region 3, for example, is implanted with boron (B) , which is a p-type impurity, by ion implantation and thermal diffusion. As a result of this process, a p-type base region 3 is formed at a depth of about 1 μm from the surface 2a. Then n-type drift layer 1 is formed between p-type base region 3 and n-type drain layer 31, and the n-type source region 5 is, for example, formed by selectively implanting the dopant Arsenic (As).

The edge of the gate electrode 13 adjacent to the open-end of trench 11 extends upwardly, to overlap, in the z direction, the terminus of the n- type source region 5 inwardly of the base region 3, the p type base region 3 extends partially below, in the z direction, the n-type source region, and the electrode 13 extends further inwardly to extend adjacent to a portion of drift region 1. As a result, portions of gate electrode are opposed to n-type drift layer 1, p-type base region 3, and n-type source region 5 across gate insulator 17. As a result of the MOS channel that has been formed between p-type base region 3 and gate insulator 17, it is possible to control the drain current that flows from n-type drift layer 1 to n-type source region 5.

Now, as shown in FIG. 5B, interlayer dielectric 29 is formed on gate electrode 13, such as by a dielectric cvd process to form a blanket film layer over the exposed portions of the feature, which is pattern etched to form interlayer dielectric, and p-type contact region 7 is formed on the surface of p-type base region 3 using ion implant techniques or thermal diffusion techniques to infuse a p type dopant into the

The process is continued, as shown in FIG. 5C, to complete the semiconductor device 100 by forming source electrode 35 and drain electrode 33. Source electrode 35 covers interlayer dielectric 29 by contacting the surface of p-type contact region 7 and n-type source region 5. On the other hand, drain electrode 33 is provided, for example, on the back side of n-type drain layer 31. Both electrodes may be deposited by cvd processes.

In this embodiment of semiconductor device 100, on-resistance and input capacitance are reduced, which also enables power loss reduction. For example, most power loss in a MOSFET results from conduction loss due to on-resistance (RON) or from switching loss at power-on. In order to reduce power loss, it is good to reduce RON and input capacitance (CISS). CISS is the sum of gate-to-source capacitance (CGS) and gate-to-drain capacitance (CGD).

With semiconductor device 100, by reducing the capacity between field plate electrode 15, which is connected to the source electrode and gate electrode 13, CGS will be reduced and so will be CISS. More precisely, field plate electrode 15 is opposed to the lower part 13c of gate electrode 13 across the edge 15b of a thin insulator 27, as compared to other insulator 27 thicknesses between the electrodes 13, 15 and adjacent doped drain region 1. Also, the area of the edge 15b of field plate electrode 15 is smaller, as compared to the opposed or facing area of the lower part 13c of gate electrode 13. As a result, it is possible to reduce gate-to-source capacitance inside trench 11.

In addition, referring again to FIG. 1, gate electrode 13 includes the first part 13a and the second part 13b. The second part 13b is opposed to n-type drift layer 1 across field plate insulator 21. Then, because the thickness in direction X of field plate insulator 21 is thinner as compared to the thickness in direction X of field plate insulator 23, which is sandwiched between field plate electrode 15 and n-type drift layer 1, the drain-source breakdown voltage is been improved.

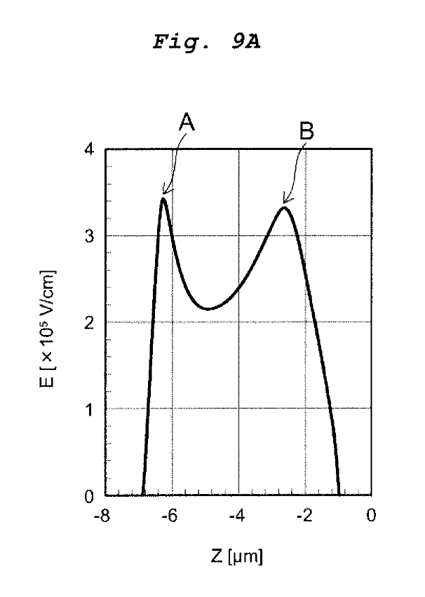

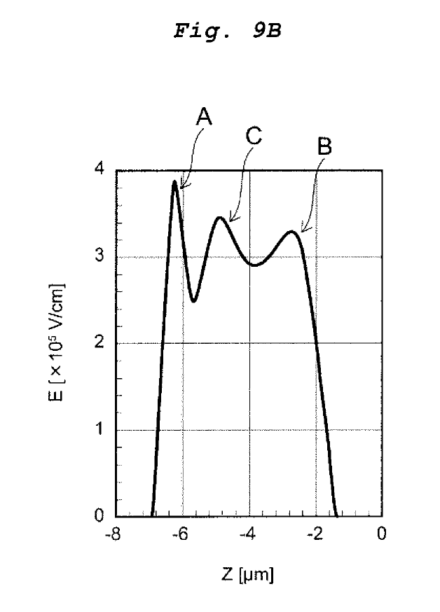

For example, FIG. 9A and FIG. 9B are graphs showing the electric field distribution of n-type drift layer 1 in direction Z. More precisely, if a MOS channel is set to the off state, these figures show the resulting drain-source breakdown voltage. That is, as shown in FIG. 9A and FIG. 9B, the integral value in direction Z, which represents the electric field distribution, is equal to each breakdown voltage.

FIG. 9A shows the electric field distribution in the case where field plate insulator 21 and field plate insulator 23 have the same thickness. FIG. 9B shows the electric field distribution in the case where the thickness of direction X of field plate insulator 21 is 0.3 μm, the thickness of field plate insulator 23 is 0.6 μm, and the thickness of direction Z of field plate insulator 25 in the bottom of trench 11 is 0.25 μm.

In the example shown in FIG. 9A, the electric field has reached its peak B at the edge of the bottom trench 11, peak electric field A has been reached at the depth of the lowest part of the first part 13a of gate electrode 13. On the other hand, in the example shown in FIG. 9B, the electrical field C has also reached its peak at the depth corresponding to the second part 13b of gate electrode 13. As a result, the breakdown voltage that corresponds to the electric field distribution shown in FIG. 9B becomes higher compared to the breakdown voltage that corresponds to the electric field distribution shown in FIG. 9A.

More precisely, the drain-source breakdown voltage can be improved by reducing the thickness in direction X of field plate insulator 21 to make it thinner than the thickness in direction X of field plate insulator 23, as well as by reducing the thickness in direction Z of field plate insulator 25 to make it thinner than the thickness in direction X of field plate insulator 23. As a result, by maintaining the prescribed breakdown voltage and by increasing the carrier density of n-type drift layer 1, it is possible to reduce the resistance, including the on-resistance (RON).

In addition, the cross-sectional area of gate electrode 13 becomes wider, because it includes the second part 13b, which extends to the bottom side of trench 11. This enables the reduction of the gate resistance.

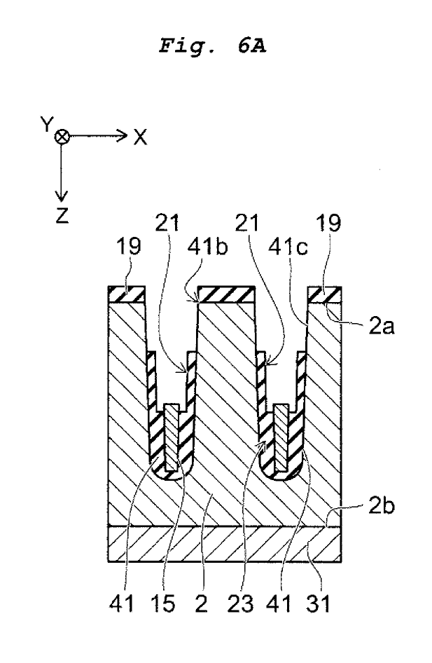

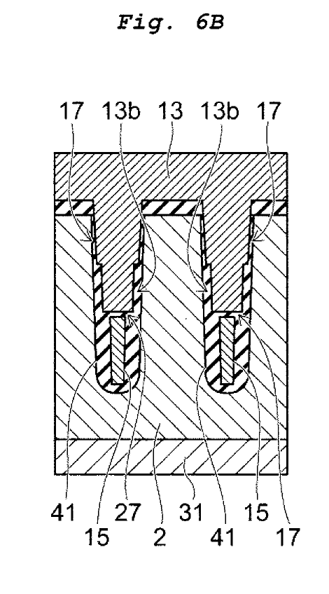

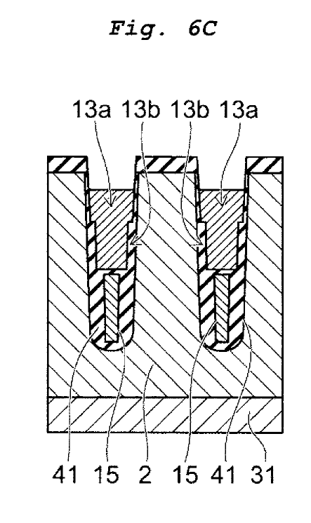

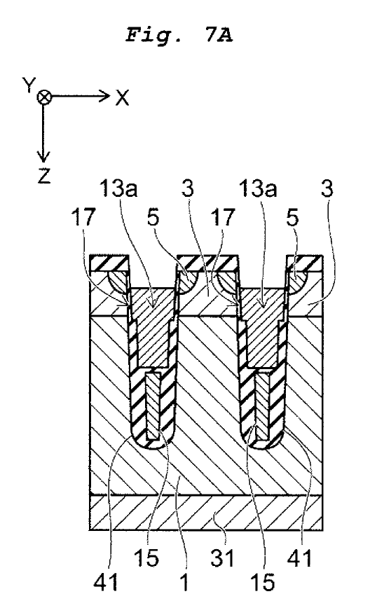

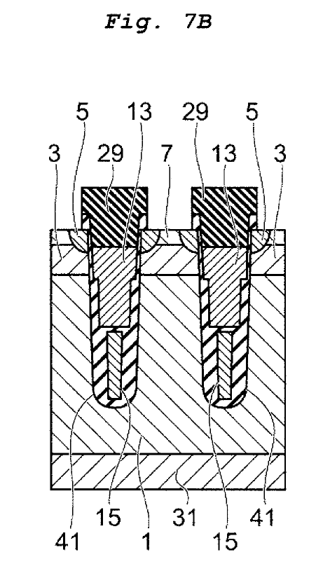

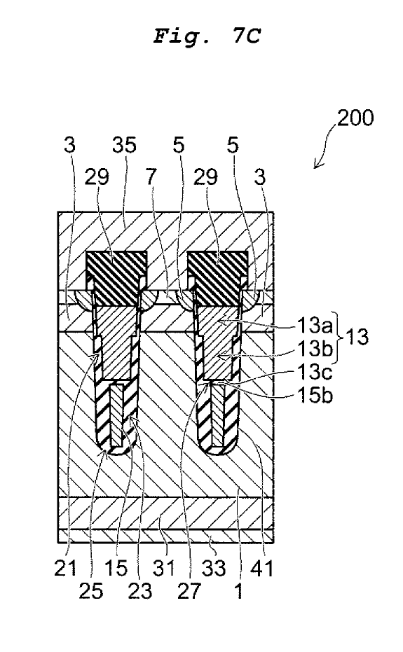

FIGS. 6A to 7C illustrate the manufacturing method of the semiconductor device 200 according to a modification on the first described embodiment. FIGS. 6A to 7C are schematic sectional profiles representing the manufacturing process of the semiconductor device 200.

As shown in FIG. 6A, adjacent trenches 41 are formed in direction Z from the surface 2a of n-type layer 2, and the trenches extend inwardly and outwardly of the page in direction y. The width in direction X of the opening side 41b of trench 41 is narrower compared to trench 11 in the embodiment shown with respect to FIGS. 2 to 5 here, for example; it is 1 μm or less.

Inside each trench 41, a field plate electrode 15 is provided within field plate insulator 23. Field plate electrode 15 is opposed to, or adjacent to, the n-type layer 2, separated therefrom by field plate insulator 23. In addition, field plate insulator 21 is formed on the opening side of field plate insulator 23, by, for example, forming an insulator layer to line the trench 41, etching a trench shaped aperture into the insulator material, depositing the field plate electrode 15 material into the trench shaped aperture and etching it back to a desired depth in the trench shaped aperture, and then wet etching the insulating material to form a thinner region thereof (as compares to field plate insulator 23, to become field plate insulator 21, without significantly etching the field plate insulator 23 while exposing the uppermost portions of the side walls of the trench 21. The manufacturing process in FIG. 6A may be the same at those illustrated in FIG. 2A to FIG. 4A.

Next, as shown in FIG. 6B, the now exposed side walls of the trench 41 are thermally oxidized, to for the gate insulator 17 which will isolate the gate electrode 13 in the trench 41. Thereafter, a gate electrode material 13 is deposited over the gate insulator 21 and thinner gate insulator 21.

FIG. GC shows the process to continue to etch back gate electrode 13 and remove the portion of the material deposited to form the gate electrode from the surface 2a of n-type layer 2 and a portion of the gate insulator 17 closest to the opening of the trenches 41. As a result, inside trench 41, the first part 13a of gate electrode 13 and the second part 13b are formed.

In this embodiment, because the width in direction X of opening side 41b is narrow, it is possible to flatten the surface of gate electrode 13, which is embedded in trench 41. Therefore, to etch back gate electrode 13, it is possible to use an isotropic etching technique such as the CDE (chemical dry etching) technique.

Next, as shown in FIG. 7A, is the formation of the p-type base region 3 and n-type source region 5 on the surface 2a of n-type layer 2. P-type base region 3 is formed by ion implantation and thermal diffusion of p-type dopants. N-type source region 5 is formed by the selective ion implantation of n-type dopants. Then, n-type drift layer 1 is formed between n-type drain layer 31 and p-type base region 3.

Now, as shown in FIG. 7B, interlayer dielectric 29 is formed on gate electrode 13, such as by blanket cvd deposition of a conductive material, which is pattern etched to provide individual electrodes over each trench. Also, p-type contact region 7 is formed on the surface of p-type base region 3.

FIG. 7C shows the process to complete semiconductor device 100 by forming source electrode 35 and drain electrode 33. Source electrode 35 maybe also deposited by cvd techniques and covers interlayer dielectric 29 by contacting the surface 2a of n-type source region 5 and p-type contact region 7. On the other hand, drain electrode 33 is deposited by for example a cvd technique, and is provided on the back side 2b of n-type drain layer 31.

Even in the case of this modified structure, the thickness in direction X of field plate insulator 21, which is sandwiched between the second part 13b of gate electrode 13 and n-type drift layer 1, is thinner compared to that of field plate insulator 23, which is sandwiched between field plate electrode 15 and n-type drift layer 1. Also, the thickness in direction Z of field plate insulator 25, which is formed in the bottom of trench 41, is thinner compared to the thickness in direction X of field plate insulator 23. As a result, it is possible reduce on-resistance (RON) by increasing the carrier density of n-type drift layer 1.

In addition, the area of the edge 15b of field plate electrode 15, which is opposed to the lower part 13c of gate electrode 13, is narrower compared to the area of the lower part 13c of gate electrode 13. This enables the reduction in gate-to-source capacitance.

Also, in this embodiment, by using a simple manufacturing method, it is possible to achieve the trench gate structure, which includes field plate electrode 15, which is opposed to n-type drift layer 1, through different thicknesses of field plate insulators as well as the second part 13b of gate electrode 13. More precisely, by etching field plate insulator 23, which is provided inside the trench, field plate insulator 21, which is the second insulator, is formed. Then, the conductivity layers embedded inside the trench are the only two layers suitable for field plate electrode 15 and gate electrode 13. As a result, it is possible to achieve the semiconductor device with reduced on-resistance (RON) and input capacitance (CISS) at low cost.

### EMBODIMENT 2

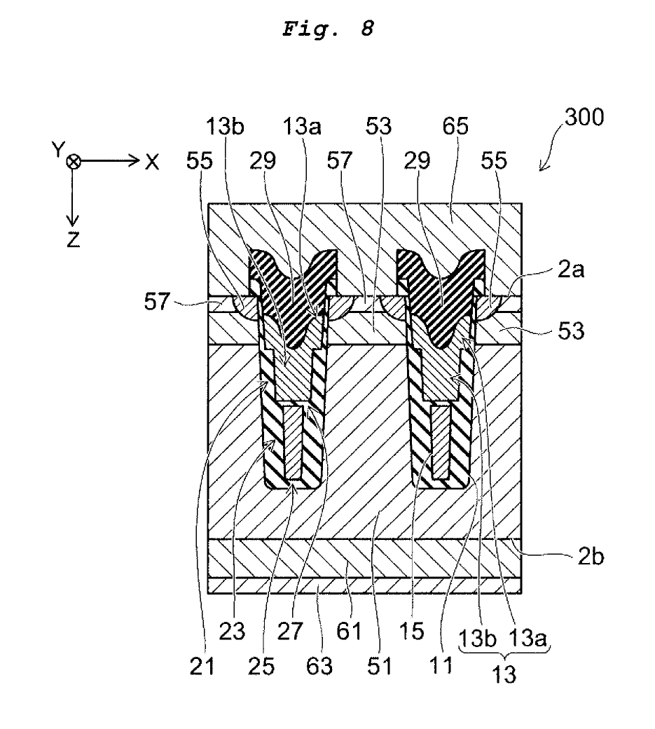

FIG. 8 is a schematic profile representing the semiconductor device 300 in the second embodiment. The semiconductor device 300 is a bipolar transistor with insulated gates, or the so-called IGBT (insulated gate bipolar transistor).

The semiconductor device 300 provides n-type base layer 51, which is the semiconductor layer of the first conductivity type, p-type base region 53, which is the first region of the second conductivity type, n-type emitter region 55, which is the second region of the first conductivity type, and p-type contact region 57, which is the third region of the second conductivity type.

P-type base region 53 is provided on the top of n-type base layer 52. N-type emitter region 55 is selectively provided on p-type base region 53; one part of this invades the interior of p-type base region 53. P-type contact region 57 is selectively provided after adjoining n-type emitter region 55 to the top of p-type base region 53.

Gate electrode 13 which is the first control electrode is provided inside trench 11, which is formed by n-type base layer 51. Trench 11 is provided, for example, by a stripe that extends vertically in direction Y on side XZ; the depth in direction Z is deeper compared to that of p-type base region 53. Then, between the bottom 11a of trench 11 and gate electrode 13, field plate electrode 15, which is the second control electrode, is provided.

Gate electrode 13 includes the first part 13a and the second part 13b. The first part 13a is opposed to p-type base region 53 and n-type emitter region 55, separated by gate insulator 17 (the first insulator). The second part 13b is opposed to n-type base layer 51, separated by field plate insulator 21 (the second insulator), which is even thicker than gate insulator 17.

Field plate electrode 15 is opposed to n-type base layer 51, separated by field plate insulator 23 (the third insulator), whose thickness in direction X is thicker compared to that of field plate insulator 21. Also, field plate electrode 15 is opposed to n-type base layer 52, separated by field plate insulator 25 (the fourth insulator) in the bottom of trench 11. The thickness in direction Z of field plate insulator 25 is thinner than that of field plate insulator 23 in direction X.

Field plate electrode 15 is opposed to gate electrode 13, separated by insulator 27, which is the fifth insulator. And the area of the part that is opposed to gate electrode 13 to field plate electrode 15 is smaller compared to the entire area where gate electrode 13 and field place electrode 15 face each other.

The semiconductor device 300 includes p-type collector layer 61, which is connected to the back side 2b of n-type base layer 51. Then, collector electrode 63 (the first main electrode), which has been electrically connected to p-type collector layer 61, is prepared. Also, the semiconductor device 300 provides emitter electrode 65 (the second main electrode), which has been electrically connected to p-type contact region 57 and n-type emitter region 55 on the surface 2a of p-type contact region 57 and n-type emitter region 55.

The semiconductor device 300 includes the first part 13b of gate electrode 13, which is opposed to n-type base layer 51 across field plate insulator 21. The thickness indirection Z of field plate electrode insulator 25 from the bottom of trench 41 is thinner compared to the thickness in direction X of field plate insulator 23. This enables a higher carrier density of n-type base layer 51 to be set in order to reduce on-resistance (RON). Also, reducing the capacity between field plate electrode 15 and gate electrode 13 enables the reduction of switching loss.

While certain embodiments have been described, these embodiments have been presented by way of example only, and are not intended to limit the scope of the embodiments. Indeed, the novel embodiments described herein may be embodied in a variety of other forms; furthermore, various omissions, substitutions and changes in the form of the embodiments described herein may be made without departing from the spirit of the embodiments. The accompanying claims and their equivalents are intended to cover such forms or modifications as would fall within the scope and spirit of the embodiments.

What is claimed is:

1. A semiconductor device comprising;
a semiconductor layer of a first conductivity type;
a first region, of a second conductivity type, provided on a first surface of the semiconductor layer of the first conductivity type;
a second region, of the first conductivity type, provided selectively on the first region;
a third region, of the second conductivity type, which is provided selectively and is adjoined to the second region, on the first region;
a trench, extending through the first region and the second region, and extending inwardly of, and terminating within, the semiconductor layer of a first conductivity type;
a first control electrode disposed within the trench, the electrode having a first end situated to oppose a portion of the second region; the first control electrode including a first part, which is opposed to the first and the second region through a first insulator, and a second part, which is opposed to the semiconductor layer through a second insulator, the second insulator having a thickness separating the second part of the electrode from the adjacent semiconductor layer having a first conductivity type which is thicker than the thickness of the first insulator extending between the first part of the first electrode and the adjacent first region and second region;
a second control electrode, which is formed within the trench between the terminus of the trench in the semiconductor layer of a first conductivity type, and the first control electrode; the second control electrode is opposed to the semiconductor layer, through a third insulator, and the third insulator is thicker than the thickness of the second insulator separating the second part of the electrode from the adjacent semiconductor layer having a first conductivity type;
a first electrode, which is electrically connected to the semiconductor layer of a first conductivity type; and
a second electrode, which is electrically connected to the second and third regions.

2. The semiconductor device according to claim 1, wherein
the second control electrode is opposed to the semiconductor layer through a fourth insulator disposed between the second control electrode and the terminus of the trench in the semiconductor layer of the first conductivity type, the fourth insulator having a thickness extending between the second control electrode and the terminus of the trench which is less than the thickness of the third insulator.

3. The semiconductor device of claim 1, wherein
the second control electrode is electrically connected to the second main electrode.

4. The semiconductor device of claim 3, wherein
the second control electrode is opposed to the first control electrode through a fifth insulator; and
the area of the part of the second control electrode that is opposed to the first control electrode is smaller than the area of the first control electrode facing the second control electrode face each other.

5. The semiconductor device of claim 4, wherein the peak voltage of the gate electrode occurs at the second at the second insulator.

6. The semiconductor device of claim 1, wherein the second insulator, the third insulator, and the fourth insulator material are a single continuous material.

7. The semiconductor device of claim 6, wherein the first insulator is a different material from that compromising the second insulator, the third insulator and the fourth insulator.

8. The semiconductor device of claim 1, wherein the semiconductor layer of a first conductivity type has a second surface opposed to the first surface thereof, and the first main electrode is disposed on the second side of the semiconductor layer of the first conductivity type.

9. A method for manufacturing a semiconductor device comprising the steps of:
providing a semiconductor layer of a first conductivity type and having a first field surface and a second, opposed, surface;
extending a trench from the field surface inwardly of the semiconductor layer of a first conductivity type;
depositing an insulating layer over the field side and surfaces of the trench, leaving a smaller, trench shaped void therein;
depositing a field electrode material into the trench shaped void;
etching the insulating film, disposed adjacent to the field side of the semiconductor layer, to thereby thin the first portion of the insulating film to a first depth;
etching back the field electrode material to form the field electrode having an upper face;
etching the insulating film to reduce the sidewall thickness thereof in a second region between the first region and the base of the trench, and simultaneously remove the first portion of the insulator, to yield a second insulator layer having a second thickness and leaving a third insulating layer intermediate of the field electrode and adjacent trench wall, having a third thickness greater than the second thickness;
oxidizing the exposed portion of the trench wall to form a first insulating layer in the trench, the first thickness of the first thickness insulating layer being less that the thickness of the second layer;
forming a fourth insulating layer, having a fourth thickness, over the exposed surface of the field electrode to form a fourth insulating layer;
depositing a second electrode material into the remaining trench like opening; and
etching second electrode material to form a gate electrode contacting both the first insulating layer and the

10. The semiconductor device of claim 9, further including the step of thinning the base of the insulating layer in the trench prior to depositing the first electrode material.

11. The method of forming a semiconductor device of claim 9, wherein the surface of the field electrode facing the gate electrode is smaller than the adjacent face of the gate electrode.

12. The method of forming a semiconductor device of claim 9, further including forming a gate dielectric layer over the gate electrode.

13. The method of forming a semiconductor device of claim 12, further including depositing an electrode over the gate electrode;

14. The method of forming a semiconductor device of claim 11, further including:
forming a first doped region of opposite conductivity to the first semiconductor layer within the field surface of the first semiconductor layer.

15. The method of forming a semiconductor device of claim 14 including forming a second doped region, of the same conductivity type as the semiconductor layer, adjacent to the first doped region.

16. The method of forming a semiconductor device of claim 15 including forming a third doped region, of the same conductivity type as the first doped region, adjacent to both the first doped region and the second doped region.

17. The method of forming a semiconductor device of claim 16, further including forming a drain layer at the second surface of the semiconductor layer having the same conductivity as the semiconductor layer.

18. The method of forming a semiconductor device of claim 17, wherein the first conductivity type is n-doped.

19. The method of forming a semiconductor device of claim 17, wherein the dopant concentration in the drain layer is greater than the dopant concentration in the first semiconductor layer.

20. The method of forming a semiconductor device of claim 19, wherein the breakdown voltage of the insulator adjacent the gate electrode is greatest in the second insulating layer.
